(19) United States
(12) Patent Application Publication
(10) Pub. No.: US 2015/0279479 A1
(43) Pub. Date: Oct. 1, 2015

(54) ANTI-FUSE ONE-TIME PROGRAMMABLE RESISTIVE RANDOM ACCESS MEMORIES

(71) Applicant: QUALCOMM Incorporated, San Diego, CA (US)

(72) Inventors: Xia LI, San Diego, CA (US); Wei-Chuan CHEN, Taipei (TW); Seung Hyuk KANG, San Diego, CA (US); Kangho LEE, San Diego, CA (US)

(73) Assignee: QUALCOMM Incorporated, San Diego, CA (US)

(21) Appl. No.: 14/283,154

(22) Filed: May 20, 2014

Related U.S. Application Data
(60) Provisional application No. 61/973,712, filed on Apr. 1, 2014.

(51) Int. Cl. G11C 17/18; G11C 13/00; G11C 17/16

(52) U.S. Cl. CPC G11C 17/18; G11C 17/16; G11C 13/0069; G11C 13/004; G11C 2013/0042

(57) ABSTRACT

An anti-fuse device includes a first electrode, an insulator on the first electrode, a second electrode on the insulator, and selector logic coupled to the second electrode. The device also includes a conductive path between the first and second electrodes. The conductive path may be configured to provide a hard breakdown for one-time programmable non-volatile data storage.

### CROSS REFERENCE TO RELATED APPLICATION

The present application claims the benefit of U.S. Provisional Patent Application No. 61/973,712 filed on Apr. 1, 2014, in the names of Xia Li et al., the disclosure of which is expressly incorporated by reference herein in its entirety.

### TECHNICAL FIELD

The present disclosure generally relates to resistive random access memory (RRAM) design and fabrication. More specifically, the present disclosure relates to anti-fuse one-time programmable (OTP) random access memories.

### BACKGROUND

Non-volatile memories (NVM) may include memory cells as basic switching elements to store data. A one-time programmable (OTP) non-volatile memory is a form of digital memory, and a set value of each bit is locked by a fuse or anti-fuse. In a OTP memory, the set value of each bit cell cannot be reset. By contrast, in a multiple-time programmable (MTP) memory, a number of write cycles can be supported, versus the OTP memory in which data is permanently stored and cannot be changed.

MTP devices may employ a switching element such as a transistor to toggle between the different states. Unfortunately, frequently switching between such states may lead to excessive current variation, as well as the soft breakdown and rupture of an MTP device. Prolonged switching activity may also eventually lead to permanent damage of the materials in the MTP device. For this reason, MTP devices also have limited data retention spans as well as endurance. The memory storage capabilities of MTP devices may also be temporary.

### SUMMARY

An anti-fuse device includes a first electrode, an insulator on the first electrode, a second electrode on the insulator, and selector logic coupled to the second electrode. The device also includes a conductive path between the first and second electrodes. The conductive path may be configured to provide a hard breakdown for one-time programmable non-volatile data storage.

A method of programming and reading a one-time programmable (OTP) device includes driving a current within a first cell(s) of a resistive random access memory (RRAM) array. Driving of the current with the first cell(s) may cause a hard breakdown of the first cell(s) to provide one-time programming of data within the first cell(s). The method also includes reading the data from the first cell(s).

An anti-fuse device includes a first electrode, an insulator on the first electrode, a second electrode on the insulator, and selector logic coupled to the second electrode. The device also includes a means for conducting between the first and second electrodes. The conducting means causes a hard breakdown for one-time programmable non-volatile data storage.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 shows a schematic view of a conventional resistive random access memory (RRAM) multiple-time programmable (MTP) device.

FIG. 2 shows a schematic view of a RRAM anti-fuse one-time programmable (OTP) device according to an aspect of the disclosure.

FIG. 3A shows a memristor effect of RRAM devices according to an aspect of the disclosure.

FIG. 3B shows a graph illustrating a memristor effect of RRAM devices according to an aspect of the disclosure.

FIG. 4 is a process flow diagram illustrating a process to use a RRAM anti-fuse OTP device according to an aspect of the disclosure.

FIG. 5 is a block diagram showing an exemplary wireless communication system in which a configuration of the disclosure may be advantageously employed.

FIG. 6 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

Non-volatile memories (NVM) may include memory cells as basic switching elements to store data. A one-time programmable (OTP) non-volatile memory is a form of digital memory in which a set value of each bit is locked by a fuse or anti-fuse. In a OTP memory, the set value of each bit cell cannot be reset. By contrast, in a multiple-time programmable (MTP) memory, a number of write cycles can be supported, versus the OTP memory in which data is permanently stored and cannot be changed.

MTP devices often employ a switching element such as a transistor to toggle between different states. Unfortunately, frequent switching between such states may lead to excessive current variation, as well as soft breakdown and rupture of an MTP device. Prolonged switching activity may also eventually lead to permanent damage of the materials in the MTP device. For this reason, MTP devices also have limited data retention spans as well as endurance. The memory storage capabilities of MTP devices may also be temporary.

In one aspect of the present disclosure, a resistive random access memory (RRAM) provides an anti-fuse OTP device that exhibits performance improvements over OTP devices. The anti-fuse OTP device may include a first electrode, an insulator on the first electrode and a second electrode on the insulator. The anti-fuse OTP also includes selector logic coupled to the second electrode. In this arrangement, the anti-fuse OTP device includes a conductive path between the first and second electrodes configured to provide a hard breakdown for one-time programmable non-volatile data storage.

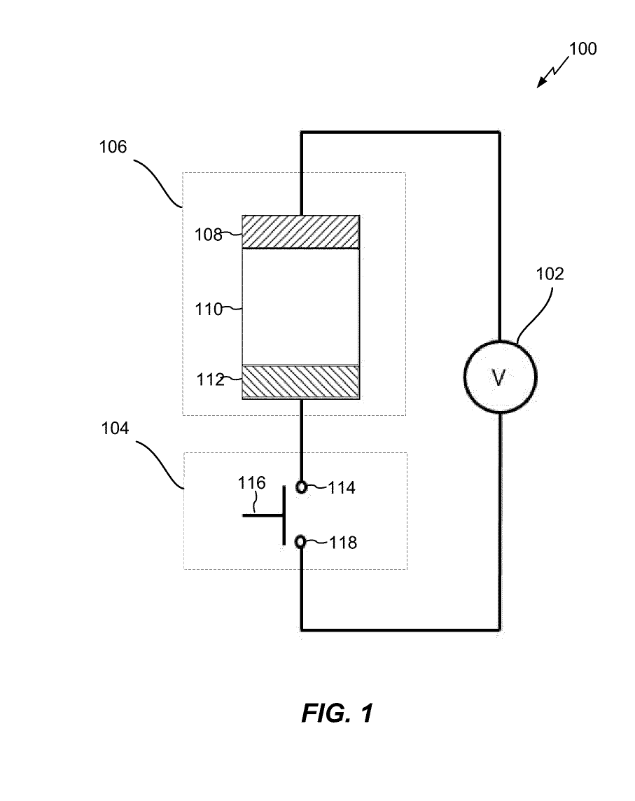

FIG. 1 shows a schematic view of a resistive random access memory (RRAM) multiple-time programmable (MTP) device 100. The MTP device 100 includes a voltage source 102, a switching element 104 and a resistive element 106. The switching element 104 may be a transistor, and also includes a gate 116, a first terminal 114 and a second terminal 118. The resistive element 106 functions as a resistor and also includes a first electrode 108, an insulator layer 110 and a second electrode 112. The resistive element 106 can also be a metal insulator metal (MIM) structure, as shown in FIG. 1.

The switching element 104 may provide a memory function such as data writing. To write date, the switching element 104 may control the feeding of a voltage from the voltage source 102 into the resistive element 106. Feeding of the voltage may cause the resistive element 106 to switch between states such as a resistance high state (RHS) and a resistance low state (RLS). Unfortunately, this constant switching between the high and low states may cause the resistive element 106 to experience a soft breakdown and/or rupture. Repeated programming and resetting of the MTP device 100 with multiple write cycles may also cause the soft breakdown or rupture of the resistive element 106 of the MTP device 100. As described herein, a “soft breakdown” may refer to the degradation of RRAM materials or ceasing of RRAM functionality at lower voltages or lower current levels, which may happen more frequently because lower voltages or currents are often used in RRAM devices. The “soft breakdown” effect can also be reversed by a low voltage or current. A soft breakdown may create a conductor filament between the first electrode 108 and the second electrode 112 through the insulator layer 110 for conducting current through the resistive element 106.

The MTP device 100 may include a 1R1T (1 resistor, 1 transistor) cell area. The density of the MTP devices is also high, and the data retention for devices may be limited and finite (e.g., 10 years). The MTP device 100 may also be used in temporary or non-volatile memory solutions such as embedded memories or flash memories.

The MTP device 100 may undergo a “set” process by going from a “zero” current and a high resistance to an intermediate value (e.g., a temporary “set” voltage or Vtset at roughly 10 μA, 0.625 V), and then to a high current, low resistance value (at a “set” voltage, or Vset at roughly 25 μA, 1.5 V). The MTP device 100 may also undergo a “reset” process by changing from zero current to a high current, low resistance value (e.g., a temporary “reset” voltage, Vtres at roughly 20 μA, 0.5 V), then to a low current, high resistance value (e.g., a “reset” voltage, or Vres at roughly 18 μA, 1.5 V), and then back to zero current. The low resistance and high resistance may have a large variation at a fixed current of roughly 25 μA.

The MTP device 100 is similar to non-volatile memory that experiences conductive filament soft breakdown and/or rupture by exposure to excessive levels of current or voltage switching. For example, the MTP device can switch high to low and vice versa a finite number of times before experiencing some type of breakdown. Furthermore, RRAM devices can be switched by high temperatures, which leads to limited data retention. Also, the stored data of the MTP device 100 may be unintentionally changed, which can lead to loss of the data.

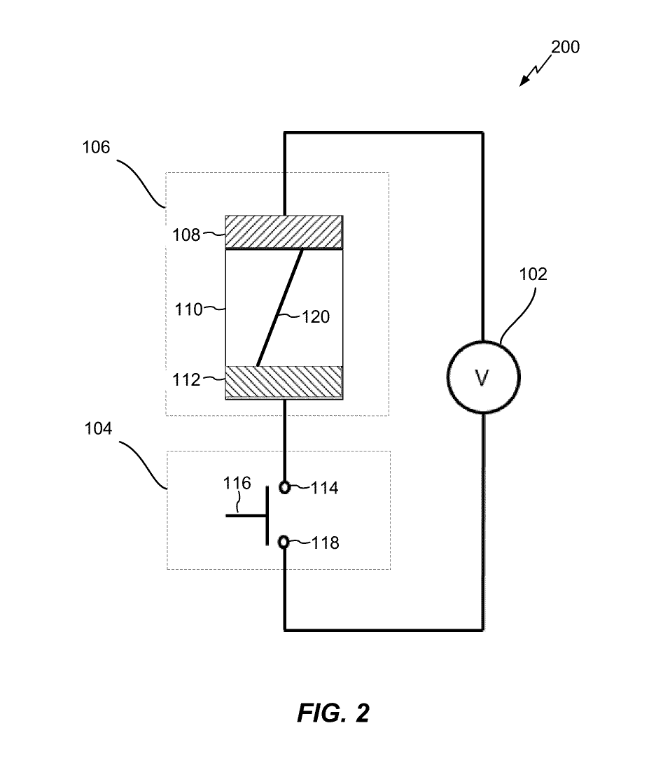

FIG. 2 shows a schematic view of an RRAM anti-fuse one-time programmable (OTP) device 200 according to an aspect of the disclosure. An anti-fuse connection or short (e.g., the anti-fuse short 120) may be configured with a high resistance and is designed to permanently create an electrically conductive path across the anti-fuse device when the voltage across the anti-fuse exceeds a certain level. This permanent conductive path may be referred to as a hard breakdown of the anti-fuse. Conventionally, a hard breakdown of an RRAM memory cell is undesirable and treated as a device failure. That is, hard breakdown of an RRAM memory cell is generally avoided and causes the device to be classified as a failing device that is ignored and not used during operation.

In one aspect of the present disclosure, the RRAM anti-fuse OTP device 200 undergoes a hard breakdown to enable permanent storage of data to provide a performance improvement over the MTP device 100. The hard breakdown occurs due to permanent damage to the dielectric caused by a high current or voltage value. That is, the hard breakdown forms a conductive path that cannot be removed or restored. The RRAM anti-fuse OTP device 200 may have similar elements to the MTP device 100 of FIG. 1. In this configuration, the RRAM anti-fuse OTP device 200 exhibits an anti-fuse short 120 that couples the first electrode 108 to the second electrode 112. The anti-fuse short 120 forms a permanent short between the first electrode 108 and the second electrode 112 through the insulator layer 110 to enable permanent, OTP storage of data.

The anti-fuse short 120 of the resistive element 106 is limited to hard breakdown by avoiding soft breakdown or rupture. In one aspect, hard breakdown refers to the degradation of RRAM materials or ceasing of RRAM functionality only at higher voltages or higher current levels, which happens less because higher voltages or currents are rarely used in RRAM devices. Also, because of its OTP functionality, the RRAM anti-fuse OTP device 200 only writes and stores data once, as opposed to having to switch many times as in the case of the MTP device 100. Once programmed, the OTP data can be read from the RRAM anti-fuse OTP device 200.

The density of the RRAM anti-fuse OTP device 200 may be less than the high density of the MTP device 100, as shown in FIG. 1. The array size of the RRAM anti-fuse OTP device 200 may also be smaller than conventional OTP devices. RRAM OTP devices can also co-exist with RRAM MTP devices, and similar processes may manufacture both devices. By fabricating both OTP and MTP varieties, the RRAM OTP and the RRAM MTP are formed in the same array, with their peripheral circuits being different. Therefore, the RRAM anti-fuse OTP device 200 may be fabricated at a reduced manufacturing cost, with a more efficient design.

The data retention of the RRAM anti-fuse OTP device 200 is generally permanent, as opposed to the limited data retention (e.g., 10 years) of conventional MTP devices. The endurance of a RRAM anti-fuse OTP device 200 is also much higher compared to the endurance of a MTP device. The endurance of RRAM OTP devices may be defined by the product lifetime. RRAM anti-fuse OTP devices may also be more frequently used for more permanent data storage solutions, which may also be non-volatile memories.

The RRAM anti-fuse OTP device 200 permanently stores data that cannot be changed after programming. This permanent storage is provided by the hard breakdown and the avoidance of soft breakdown or rupture switching by excessive current/voltage switching. Furthermore, the RRAM anti-fuse OTP device 200 cannot be re-programmed, or have its data disturbed or reversed by any methods. As a result, the RRAM anti-fuse OTP device 200 may permanently store ID data, analog/radio frequency (RF) circuit trim data, security data and purpose data, identification data such as fingerprints and the like.

Hard breakdown is also one of the beneficial properties of the RRAM anti-fuse OTP device 200 because hard breakdown does not occur by chance. The RRAM anti-fuse OTP device 200 also can permanently store data after programming, and prevents the reversal of data, reprogramming, or re-modified programming, especially in a low resistance state, where breakdown may be more likely to occur. The RRAM anti-fuse OTP device 200 may also be used inside an RRAM array (with only certain cells assigned for the RRAM OTP device), or may be used as only an anti-fuse component for logic, analog or RF circuits.

The RRAM anti-fuse OTP device 200 may also be implemented in differential or multi-cells-per-bit structures, which can improve read sense amplifier performance. Also, using multiple pulses, step voltage signals or current sweeps can improve the reliability and performance of RRAM OTP devices. RRAM OTP devices are also compatible with RRAM MTP processes/devices, and there are no additional process costs associated with using an RRAM OTP device with, or instead of an RRAM MTP device. Furthermore, RRAM OTP devices may be integrated with RRAM MTP devices with no additional process costs or other problems. For example, some portions of an RRAM array may be implemented as RRAM OTP devices and some other portions may be implemented as RRAM MTP devices.

The first electrode 108 and the second electrode 112 may be a conductive material such as titanium nitride (TiN), tantalum nitride (TaN), copper (Cu), aluminum (Al) and/or platinum (Pt). The insulator layer 110 may be composed of a dielectric material including hafnium oxide (HfO₂), titanium oxide (TiOx), thallium oxide (TlO₂), tungsten oxide (W₂O₃) and/or aluminum oxide (Al₂O₃)

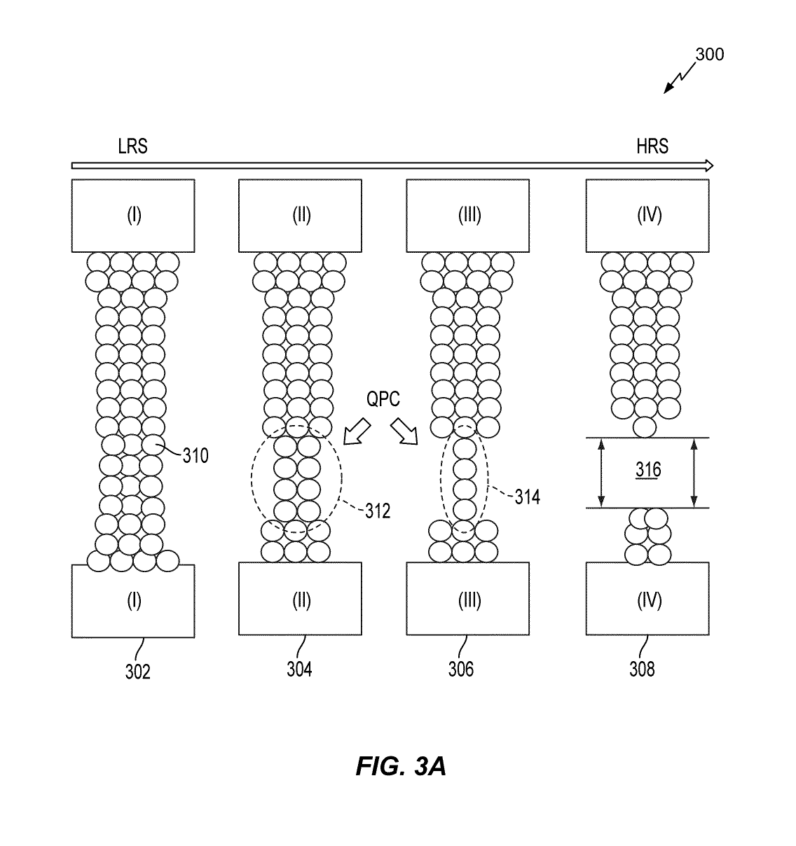

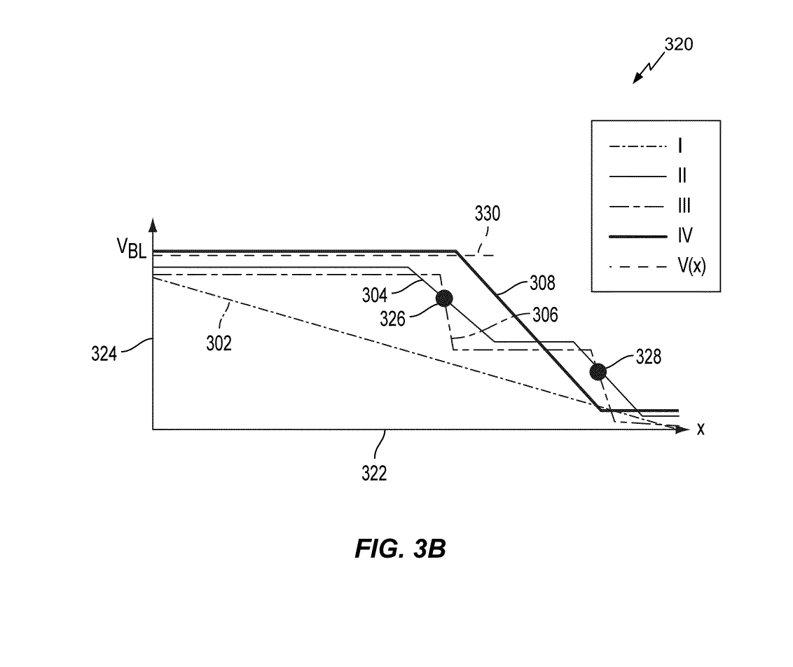

FIG. 3A shows a memristor effect of RRAM devices according to an aspect of the disclosure. A graph 300 shows a first state 302, a second state 304, a third state 306 and a fourth state 308. The first state 302 is at a low resistance state (LRS), the fourth state 308 is at a high resistance state (HRS), and the second state 304 and the third state 306 are arranged in increasing order of resistance. Each of the states show a conductor filament and the molecules within such a conductor filament. As used herein, the variable “Nc” represents the number of molecules making up the conductor filament in a particular state. The conductor filament can be the structure in between the insulator layer 110 of the resistive element 106, as shown in FIG. 2 that forms most of the resistance of the resistive element 106. The conductor filament (e.g., an oxide vacancy filament) may also be made in a dielectric material such as hafnium oxide (HfO₂), titanium oxide (TiOx), thallium oxide (TlO₂), tungsten oxide (W₂O₃), aluminum oxide (Al₂O₃), and others. The conductive path (e.g., the anti-fuse short 120), may also be a conductive material filament within a dielectric film. The conductive path or anti-fuse short 120 may also be made of a conductive material such as titanium nitride (TiN), tantalum nitride (TaN), copper (Cu), aluminum (Al), silver (Ag), and/or platinum (Pt). The conductive path may be similar to the implementation of a conductive bridging random access memory (CBRAM), a type of conductive RAM or resistive RAM.

The first state 302 shows an ohmic filament 310 of a memristor that is intact. The Nc, or number of molecules making up that ohmic filament 310 is roughly 20-100. The resistance in the ohmic filament is also at its lowest state. Damage can occur to the ohmic filament 310 in the first state 302 if high amounts of current or voltage are fed through the ohmic filament 310, which creates a permanent short such as the anti-fuse short 120 shown in FIG. 2.

The second state 304, also known as a shallow reset stage of a memristor, shows a constriction region 312 that has a Nc of roughly 8-15. The constriction region 312 undergoes a quantitative perfusion change (QPC) that lessens its number of molecules in a constriction effect. The resistance in the second state 304 is slightly higher than the resistance in the first state 302.

The third state 306, also known as a moderate reset stage of a memristor, shows a further constriction region 314 that has a Nc of roughly 1-5. The further constriction region 314 also undergoes a QPC that additionally lessens the number of molecules in a constriction effect that is even more intense than the constriction in the second state 304. The resistance in the third state 306 is slightly higher than the resistance in the second state 304.

The fourth state 308, also known as a deep reset stage of a memristor, shows a field redistribution region 316 that has Nc=0 or no molecules. In other words, the field redistribution region 316 is a gap. The resistance in the fourth state 308 is at its highest value out of all four states, and basically prevents a connection from forming in the conductor filament by being non-conducting.

An oxygen vacancy defect may lead to the formation of the conductor filament. If oxygen bonds in the molecules of the conductor filament are broken, the oxygen is released, causing an oxygen vacancy. The oxygen vacancy forms a defective energy level and a band in a dielectric bandgap. The defective energy level and band can serve as an electron or hole conductive path in the dielectric bandgap. When multiple oxygen vacancies occur, they shift the molecules around to form the conductor filament. The conductor filament can also pass electrons along its conductive path. Therefore the conductor filament forms a conductive pass (e.g., an oxygen vacancy conductive pass). The electrons also may pass through the oxygen vacancies or the molecules of the conductor filament. In one aspect, a voltage may be applied to the oxygen vacancies to remove them by moving the oxygen ions to recombine with the oxygen vacancy, thereby providing a non-conductive path within the conductor filament.

For hard breakdown, high current or voltage creates permanent damage to the dielectric bond by high heat, which results in the formation of a low resistance conductive path. This is a different process from the oxygen vacancy conductive filament formation process. In addition, the high current passing through generates heat, which melts the material and creates permanent damage to form the conductive path in the RRAM device. Hard breakdown also results in damaged oxide structures and a conductive pass or a permanent short. This damage may be similar to the anti-fuse short 120 shown in FIG. 2. When looking at a cross-section of the resistive element 106 of FIG. 2, for example, a line of damage can be seen in the RRAM material (or the insulator layer 110) that forms a conductive pass or a permanent short. The resistance of a hard breakdown conductive pass may be even lower than the low resistance state (LRS) of the first state 302.

FIG. 3B shows a graph 320 illustrating a memristor effect of RRAM devices according to an aspect of the disclosure. In the graph 320, the voltage of a bit line forms the y-axis 324 and the position along the conductor filament forms the x-axis 322. There are plots for each of the stages discussed in FIG. 3A: I, a plot for the first state 302; II, a plot for the second state 304; III, a plot for the third state 306; and IV, a plot for the fourth state 308. At the first quantitative perfusion change (QPC) point 326, the second state 304 and third state 306 plots drop in voltage and also intersect each other on the graph. At the second QPC point 328, the second state 304 and the third state 306 plots drop again in voltage and intersect each other on the graph. The first QPC point 236 and the second QPC point 328 also represent the voltage drop which occurs in the same position shown in both the second state 304 and the third state 306. The voltage function plot 330 shows a plot of voltage of the bit line as a function of the position along the conductor filament (e.g., V(x)), or the voltage cross position “x” in the conductor filament.

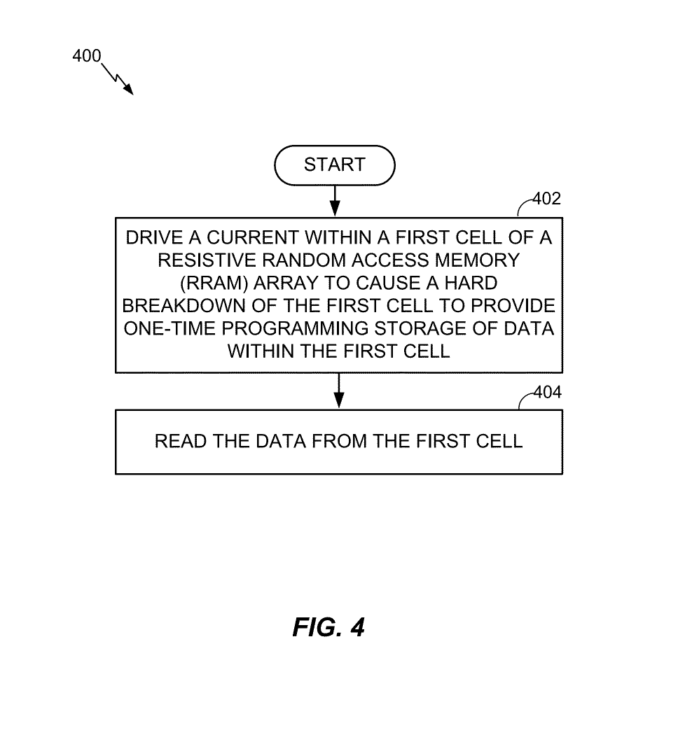

FIG. 4 is a process flow diagram illustrating a process to use an RRAM anti-fuse OTP device according to an aspect of the disclosure. In block 402, a current is driven within a first cell (e.g., the resistive element 106) of a resistive random access memory (RRAM) array to provide a hard breakdown of the first cell to provide one-time programming storage of data or one-time programming of data within the first cell. In block 404, data is read from the first cell.

In one aspect, the un-programming of a second cell of the RRAM array is performed to enter a high resistance state for high resistance storage of another data within the second cell. Furthermore, data is differentially sensed between the first cell and the second cell. This data may be sensed between the first cell and the second cell by low resistance and high resistance in different paths of a sensing amplifier.

In one aspect, the un-programming of the second cell of the RRAM array is performed to enter a low resistance state for low resistance storage of another data within the second cell. Furthermore, data is differentially sensed between the first cell and the second cell. This data may be sensed between the first cell and the second cell by low resistance and high resistance in different paths of a sensing amplifier.

In one aspect, the un-programming of a third cell of the RRAM array is performed to enter the high resistance state for high resistance storage of another data within the third cell. Cell state values are differentially sensed from the first cell, the second cell and the third cell. Furthermore, a final cell state value is determined by analyzing the cell state values differentially sensed from the first cell, the second cell, and the third cell.

In one aspect, the un-programming of the third cell of the RRAM array is performed to enter the low resistance state for low resistance storage of another data within the third cell. Cell state values are differentially sensed from the first cell, the second cell and the third cell. Furthermore, a final cell state value is determined by analyzing the cell state values differentially sensed from the first cell, the second cell, and the third cell.

In one aspect, current is driven within cells of the RRAM array to cause the hard breakdown of the cells for one-time programming storage of data within the cells. Furthermore, cell state values from the cells of the RRAM array are differentially sensed to determine a final cell state value.

In one aspect, current is driven within a second cell of the RRAM array to achieve a hard breakdown of the second cell to provide one time programming storage of another data within the second cell. A current is also driven within a third cell of the RRAM array to provide a hard breakdown of the third cell for one time programming of another data within the third cell. The cells may be one-time programmed to provide OTP function. Then, the multiple OTP cells are sensed and a final state value is obtained by analyzing multiple cell state values, or a multiple cell state value voting process. This also improves the yield, the retention and the endurance of OTP array.

In one aspect, the driving of the current is performed using multiple pulses, a higher pulse or a pulse having a longer duration. The driving of the current may be used to perform the hard breakdown.

In one configuration, a limited current is driven within a first cell of the RRAM array to cause a soft breakdown of a second cell to provide multi-time programming of data within the second cell.

In another configuration, a limited current is driven within a first cell of the RRAM array to set a low resistance state or to reset a high resistance state of a second cell to provide multi-time programming of data within the second cell.

In yet another aspect, an anti-fuse device includes a first electrode and an insulator on the first electrode. The device also includes a second electrode on the insulator and selector logic coupled to the second electrode. The device further includes means for conducting between the first and second electrodes configured to provide a hard breakdown for one-time programmable non-volatile data storage. In one aspect, the conducting means is the anti-fuse short 120. In another aspect, the aforementioned means may be any material or structure configured to perform the functions recited by the aforementioned means.

The conductive material of the various conductive material layers such as the first electrode 108 and the second electrode 112 or the anti-fuse short 120 may be titanium nitride (TiN), tantalum nitride (TaN), platinum (Pt) or copper (Cu), or other conductive materials with high conductivity. For example, such layers may include silver (Ag), annealed copper (Cu), gold (Au), aluminum (Al), calcium (Ca), tungsten (W), zinc (Zn), nickel (Ni), lithium (Li) or iron (Fe). The aforementioned conductive material layers may also be deposited by electroplating, chemical vapor deposition (CVD), physical vapor deposition (PVD), sputtering, atomic layer deposition (ALD), or evaporation.

The insulator layer 110 may be made of materials including hafnium oxide (HfO₂), titanium oxide (TiOx), thallium oxide (TlO₂), tungsten oxide (W₂O₃) and/or aluminum oxide (Al₂O₃). The insulator layer 110 and other disclosed insulating materials may also be made of materials having a low k, or a low dielectric constant value, including silicon dioxide (SiO₂) or high k dielectrics, including hafnium oxide (HfO₂), and fluorine-doped, carbon-doped, and porous carbon-doped forms, as well as spin-on organic polymeric dielectrics such as polyimide, polynorbornenes, benzocyclobutene (BCB) and polytetrafluoroethylene (PTFE), spin-on silicone based polymeric dielectrics and silicon nitrogen-containing oxycarbides (SiCON). These aforementioned layers may also be deposited by a spin-coating process, chemical vapor deposition (CVD), physical vapor deposition (PVD), sputtering, or evaporation.

Although not mentioned in the above process steps, photoresist, ultraviolet exposure through masks, photoresist development and lithography may be used. Photoresist layers may be deposited by spin-coating, droplet-based photoresist deposition, spraying, chemical vapor deposition (CVD), physical vapor deposition (PVD), sputtering, or evaporation. Photoresist layers may then be exposed and then etched by chemical etching processes using solutions such as Iron Chloride (FeCl₃), Cupric Chloride (CuCl₂) or Alkaline Ammonia (NH₃) to wash away the exposed photoresist portions, or dry etching processes using plasmas. Photoresist layers may also be stripped by a chemical photoresist stripping process or a dry photoresist stripping process using plasmas such as oxygen, which is known as ashing.

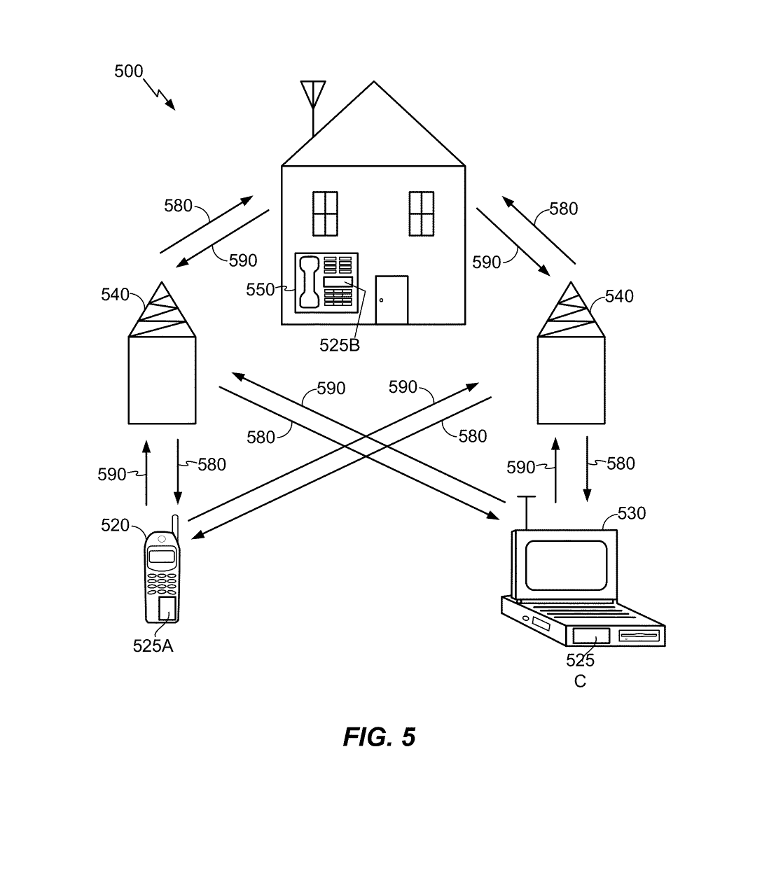

FIG. 5 is a block diagram showing an exemplary wireless communication system 500 in which an aspect of the disclosure may be advantageously employed. For purposes of illustration, FIG. 5 shows three remote units 520, 530, and 550 and two base stations 540. It will be recognized that wireless communication systems may have many more remote units and base stations. Remote units 520, 530, and 550 include IC devices 525A, 525C, and 525B that include the disclosed devices (e.g., RRAM anti-fuse OTP devices). It will be recognized that other devices may also include the disclosed devices (e.g., RRAM anti-fuse OTP devices), such as the base stations, switching devices, and network equipment. FIG. 5 shows forward link signals 580 from the base station 540 to the remote units 520, 530, and 550 and reverse link signals 590 from the remote units 520, 530, and 550 to base stations 540.

In FIG. 5, remote unit 520 is shown as a mobile telephone, remote unit 530 is shown as a portable computer, and remote unit 550 is shown as a fixed location remote unit in a wireless local loop system. For example, the remote units may be mobile phones, hand-held personal communication systems (PCS) units, portable data units such as personal data assistants, GPS enabled devices, navigation devices, set top boxes, music players, video players, entertainment units, fixed location data units such as meter reading equipment, or other devices that store or retrieve data or computer instructions, or combinations thereof. Although FIG. 5 illustrates remote units according to the aspects of the disclosure, the disclosure is not limited to these exemplary illustrated units. Aspects of the disclosure may be suitably employed in many devices, which include the disclosed devices.

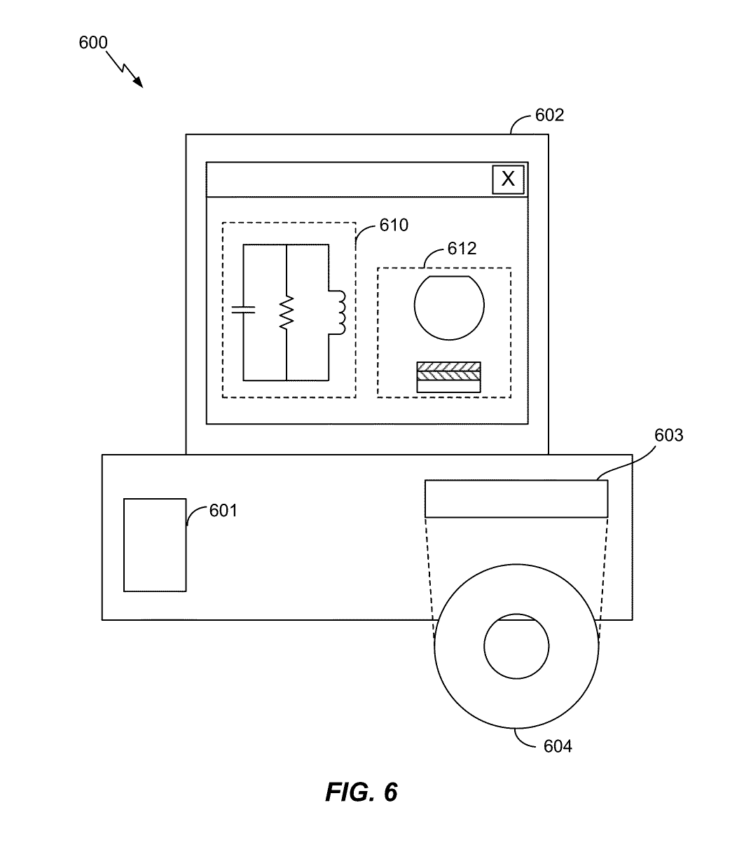

FIG. 6 is a block diagram illustrating a design workstation 600 used for circuit, layout, and logic design of a semiconductor component, such as the devices disclosed above. A design workstation 600 includes a hard disk 601 containing operating system software, support files, and design software such as Cadence or OrCAD. The design workstation 600 also includes a display 602 to facilitate the design of a circuit 610 or a semiconductor component 612 such as the disclosed device (e.g., RRAM anti-fuse OTP devices). A storage medium 604 is provided for tangibly storing the circuit design 610 or the semiconductor component 612. The circuit design 610 or the semiconductor component 612 may be stored on the storage medium 604 in a file format such as GDSII or GERBER. The storage medium 604 may be a CD-ROM, DVD, hard disk, flash memory, or other appropriate device. Furthermore, the design workstation 600 includes a drive apparatus 603 for accepting input from or writing output to the storage medium 604.

Data recorded on the storage medium 604 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 604 facilitates the design of the circuit design 610 or the semiconductor component 612 by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

What is claimed is:

1. An anti-fuse device, comprising:
a first electrode;
an insulator on the first electrode;
a second electrode on the insulator;
selector logic coupled to the second electrode; and
a conductive path between the first and second electrodes configured to provide a hard breakdown for one-time programmable non-volatile data storage.

2. The anti-fuse device of claim 1, in which the insulator is composed of a dielectric material comprising hafnium oxide (HfO₂), titanium oxide (TiOx), thallium oxide (TlO₂), tungsten oxide (W₂O₃), and/or aluminum oxide (Al₂O₃).

3. The anti-fuse device of claim 1, in which the first electrode and the second electrode comprise titanium nitride (TiN), tantalum nitride (TaN), copper, aluminum and/or platinum.

4. The anti-fuse device of claim 1, in which the selector logic comprises a transistor having a gate, a first terminal and a second terminal.

5. The anti-fuse device of claim 1, in which the conductive path is formed by applying a high voltage and current value to the insulator.

6. The anti-fuse device of claim 1 incorporated into at least one of a music player, a video player, an entertainment unit, a navigation device, a communications device, a personal digital assistant (PDA), a fixed location data unit, and a computer.

7. A method of programming and reading a one-time programmable (OTP) device, comprising:
driving a current within at least a first cell of a resistive random access memory (RRAM) array to cause a hard breakdown of the first cell to provide one-time programming of data within the first cell; and
reading the data from the first cell.

8. The method of claim 7, further comprising:
un-programming a second cell of the RRAM array to enter a high resistance state for high resistance storage of another data within the second cell; and
differentially sensing data between the first cell and the second cell.

9. The method of claim 8, further comprising:
un-programming a third cell of the RRAM array to enter the high resistance state for high resistance storage of another data within the third cell;
differentially sensing cell state values from the first cell, the second cell, and the third cell; and
determining a final cell state value by analyzing the cell state values differentially sensed from the first cell, the second cell, and the third cell.

10. The method of claim 7, further comprising:
un-programming a second cell of the RRAM array to enter a low resistance state for low resistance storage of another data within the second cell; and
differentially sensing data between the first cell and the second cell.

11. The method of claim 10, further comprising:
un-programming a third cell of the RRAM array to enter the low resistance state for low resistance storage of another data within the third cell;
differentially sensing cell state values from the first cell, the second cell, and the third cell; and
determining a final cell state value by analyzing the cell state values differentially sensed from the first cell, the second cell, and the third cell.

12. The method of claim 7, further comprising:
driving the current within cells of the RRAM array to provide the hard breakdown of the cells for one-time programming storage of data within the cells; and
differentially sensing cell state values from the cells of the RRAM array to determine a final cell state value.

13. The method of claim 7, in which driving the current is performed using multiple pulses, a higher pulse or a pulse having a longer duration.

14. The method of claim 7, further comprising driving a reduced current within at least the first cell of the RRAM array to provide a soft breakdown of a second cell to provide multi-time programming of data within the second cell.

15. The method of claim 7, further comprising driving a reduced current within at least the first cell of the RRAM array to set a low resistance state or to reset a high resistance state of a second cell to provide multi-time programming of data within the second cell.

16. The method of claim 7, further comprising incorporating the OTP device into at least one of a music player, a video player, an entertainment unit, a navigation device, a communications device, a personal digital assistant (PDA), a fixed location data unit, and a computer.

17. An anti-fuse device, comprising:
a first electrode;
an insulator on the first electrode;
a second electrode on the insulator;
selector logic coupled to the second electrode; and
means for conducting between the first and second electrodes to cause a hard breakdown for one-time programmable non-volatile storage.

18. The anti-fuse device of claim 17, in which the insulator is composed of a dialectic material comprising hafnium oxide (HfO₂), titanium oxide (TiOx), thallium oxide (TlO₂), tungsten oxide (W₂O₃), and/or aluminum oxide (Al₂O₃).

19. The anti-fuse device of claim 17, in which the first electrode and the second electrode comprise titanium nitride (TiN) and tantalum nitride (TaN), copper, aluminum and/or platinum.

20. The anti-fuse device of claim 17, in which the selector logic comprises a transistor having a gate, a first terminal and a second terminal.

21. The anti-fuse device of claim 17, in which the conducting means is formed by applying a high voltage and current value to the insulator.

22. The anti-fuse device of claim 17 incorporated into at least one of a music player, a video player, an entertainment unit, a navigation device, a communications device, a personal digital assistant (PDA), a fixed location data unit, and a computer.

23. A method of programming and reading a OTP device, comprising the steps of:
driving a current within at least a first cell of a resistive random access memory (RRAM) array to cause a hard breakdown of the first cell to provide one-time programming of data within the first cell; and
reading the data from the first cell.

24. The method of claim 23, further comprising the step of incorporating the OTP device into at least one of a music player, a video player, an entertainment unit, a navigation device, a communications device, a personal digital assistant (PDA), a fixed location data unit, and a computer.
